(19) United States
(12) Patent Application Publication
(10) Pub. No.: US 2026/0032072 A1
(43) Pub. Date: Jan. 29, 2026

(54) METHODS, SYSTEMS, AND COMPUTER READABLE MEDIA FOR ELECTRONICS DESIGN AUTOMATION (EDA) DEEP TRACING AND EVENT CORRELATION

(71) Applicant: Keysight Technologies, Inc., Santa Rosa, CA (US)

(72) Inventors: Christian Paul Sommers, Bangor, CA (US); Peter J. Marsico, Chapel Hill, NC (US)

(21) Appl. No.: 18/979,104

(22) Filed: Dec. 12, 2024

Related U.S. Application Data
(60) Provisional application No. 63/676,068, filed on Jul. 26, 2024.

(51) Int. Cl. H04L 43/50; G06F 30/31

(52) U.S. Cl. CPC H04L 43/50; G06F 30/31

(57) ABSTRACT

A method for EDA deep tracing and event correlation includes dynamically instantiating probes in a test system and an EDA emulator to capture data relating to events concerning processing or transmission of emulated data center traffic and/or traffic transmitted by the EDA emulator. The method further includes generating the emulated data center traffic, transmitting the emulated data center traffic to the EDA emulator, and receiving the traffic transmitted by the EDA emulator. The method further includes capturing, by the probes, data relating to the events concerning processing or transmission of the emulated data center traffic and/or the traffic transmitted by the EDA emulator, correlating the data, and outputting results of the correlating of the data.

### PRIORITY CLAIM

This application claims the priority benefit of U.S. Provisional Patent Application Ser. No. 63/676,068 filed Jul. 26, 2024, the disclosure of which is incorporated herein by reference in its entirety.

### TECHNICAL FIELD

The subject matter described herein relates to EDA testing. More particularly, the subject matter described herein relates to methods, systems, and computer readable media for EDA deep tracing and event correlation.

### BACKGROUND

Electronics design automation (EDA) refers to the process of designing integrated circuits using software and firmware tools, such as logic design, synthesis, and verification tools, that are used to design and test a proposed integrated circuit before the design is committed to hardware. One type of tool used in EDA is referred to as an EDA emulator. An EDA emulator emulates a hardware design so that the functionality and performance of the design can be tested prior to finalizing the design in hardware. In some cases, an EDA emulator consists of two parts: a transactor and a design under test (DUT). The emulator is a system that is capable of loading and running ASIC designs in a form that resembles the final tapeout. The ASIC design running inside the emulator is called a design under test (DUT). The transactor is a component of the emulator that simulates an external I/O entity. This entity is usually connected to the DUT through a standard interface (e.g., PCIe or Ethernet). The DUT implements its own I/O logic, such as PCIe or Ethernet logic. The transactor may also simulate certain aspects of the external interface, such as layer 1 (L1) logic and layer (L2) Ethernet logic. The transactor may also simulate characteristics of a bus or a wire that connects the external device and the DUT.

The DUT is the hardware definition language (HDL) implementation of the design being evaluated. For example, in computer networking, the DUT may be an implementation of a network chip, such as an Ethernet chip.

It is desirable to test an emulated electronics design under test under conditions that mimic the conditions that the design being evaluated will experience in operation. For example, if the emulated electronics design under test is a data center switching ASIC, then it may be desirable to generate and send emulated data center traffic to the design and monitor the performance of the design. The emulated data center traffic may include emulated impairments, such as delays and dropped packets, that mimic the impairments that will be experienced by real traffic traversing a data center switching fabric.

When testing an electronics design under test, one challenge is how and where to probe the design to determine whether the design is functioning properly and/or to diagnose problems. For example, in one test scenario, a high-level application may emulate an artificial intelligence/machine learning (AI/ML) workload. The application may pass data related to the emulated AI/ML workload to one or more traffic generators that generate packetized traffic to carry the AI/ML workload data. The traffic generators may pass the packetized traffic to a path emulation element that emulates data center switching paths and may add impairments to the traffic. The path emulation element may pass the traffic to an EDA emulator that emulates the electronics design under test, such as a data center switching or processing element. If the emulated DUT is functioning properly, the emulated DUT may generate an acknowledgement to each packet carrying the emulated AI/ML workload data and send the acknowledgement to the test system, which passes the acknowledgement back through the protocol stack to the emulated endpoint/traffic generator.

When acknowledgement does not timely reach the emulated endpoint/traffic generator, it is desirable to diagnose the problem by probing the protocol stack to determine causes of the failure. For example, it may be desirable to determine whether a packet carrying AI/ML workload data timely reached the emulated design under test and/or whether a logic error in the emulated design under test caused the emulated design under test to delay or fail to send an acknowledgement back to the sender (i.e. the emulated endpoint/traffic generator). One method for diagnosing such problems is to manually analyze packet capture data. However, manually analyzing packet capture data is a time- and labor-intensive process. Moreover, even when analysis of a packet capture file can be automated, correlating events that occur at different layers or levels in the network protocol stack can be challenging.

In light of these and other difficulties, there exists a need for improved methods, systems, and computer readable media for EDA deep tracing and event correlation.

### SUMMARY

A method for electronics design automation (EDA) deep tracing and event correlation includes dynamically instantiating a plurality of probes in a test system and an EDA emulator to capture data relating to events concerning processing or transmission of emulated data center traffic and/or traffic transmitted by the EDA emulator. The method further includes generating, by the test system, the emulated data center traffic. The method further includes transmitting, by the test system, the emulated data center traffic to the EDA emulator and receiving traffic transmitted by the EDA emulator. The method further includes capturing, by the probes, data relating to the events concerning processing or transmission of the emulated data center traffic and/or the traffic transmitted by the EDA emulator. The method further includes correlating the data relating to the events concerning the processing or transmission of the emulated data center traffic and/or the traffic transmitted by the EDA emulator. The method further includes outputting, to a test system user, results of the correlating of the data relating to the events concerning the processing or transmission of the emulated data center traffic and/or the traffic transmitted by the EDA emulator.

According to another aspect of the subject matter described herein, dynamically instantiating the probes includes dynamically instantiating at least one probe in the test system and at least one probe in the EDA emulator.

According to another aspect of the subject matter described herein, dynamically instantiating at least one probe in the test system includes instantiating a first probe for capturing data relating to emulated packets generated by the test system or packets received by the test system and a second probe for capturing data relating to emulated packets received by the EDA emulator or packets transmitted by the EDA emulator.

According to another aspect of the subject matter described herein, dynamically instantiating the probes includes dynamically instantiating the probes using in-band probe control metadata.

According to another aspect of the subject matter described herein, dynamically instantiating the probes including the in-band probe control metadata includes adding the in-band probe control metadata to or between packets in the emulated data center traffic transmitted by the test system to the EDA emulator.

According to another aspect of the subject matter described herein, dynamically instantiating the probes includes dynamically instantiating the probes using an out-of-band management interface of the EDA emulator.

According to another aspect of the subject matter described herein, dynamically instantiating the probes includes dynamically instantiating the probes in accordance with a recommendation provided by an artificial intelligence (AI) probe recommender.

According to another aspect of the subject matter described herein, generating the emulated data center traffic includes generating, at an application layer of the test system, data emulating an artificial intelligence/machine learning (AI/ML) workload and forwarding the data emulating the AI/ML workload to a traffic generator/emulator, which generates the emulated data center traffic.

According to another aspect of the subject matter described herein, the method for EDA deep tracing and event correlation includes transmitting the emulated data center traffic to a path emulation element, and at the path emulation element, emulating a data center traffic path.

According to another aspect of the subject matter described herein, emulating the data center traffic path includes adding an impairment to the emulated data center traffic and/or emulating processing or storage of the emulated data center traffic by a data center switching fabric.

According to another aspect of the subject matter described herein, a system for electronics design automation (EDA) deep tracing and event correlation is provided. The system includes a computing platform including at least one processor and a memory. The system further includes a tracing control application implemented by the at least one processor for dynamically instantiating a plurality of probes in a test system and an EDA emulator to capture data relating to events concerning processing or transmission of emulated data center traffic and/or traffic transmitted by the EDA emulator.

The system further includes an emulation endpoint/traffic generator for generating the emulated data center traffic and transmitting the emulated data center traffic to the EDA emulator. The probes are configured to capture data relating to the events concerning processing or transmission of the emulated data center traffic and/or the traffic transmitted by the EDA emulator. For instance, in the test system, one or more probes may be integrated into (or tightly coupled to) the test system's receive ports, and these receive port probes may generate metrics associated with received test traffic. In other contemplated examples, test system packet probes may be implemented using external taps or probes (virtual or physical), or software-based tap or probe agents. The system further includes an event browser/analyzer/reducer for correlating the data relating to the events concerning the processing or transmission of the emulated data center traffic and/or the traffic transmitted by the EDA emulator and outputting, to a test system user, results of the correlating of the data relating to the events concerning the processing or transmission of the emulated data center traffic and/or the traffic transmitted by the EDA emulator.

According to another aspect of the subject matter described herein, the tracing control application is configured to dynamically instantiate at least one probe in the test system and at least one probe in the EDA emulator.

According to another aspect of the subject matter described herein, the tracing control application is configured to dynamically instantiate a first probe for capturing data relating to emulated packets generated by the test system or packets received by the test system and a second probe for capturing data relating to emulated packets received by the EDA emulator or packets transmitted by the EDA emulator.

According to another aspect of the subject matter described herein, the tracing control application is configured to dynamically instantiate the probes using in-band probe control metadata.

According to another aspect of the subject matter described herein, the tracing control application is configured to add the in-band probe control metadata to or between packets in the emulated data center traffic transmitted by the test system to the EDA emulator.

According to another aspect of the subject matter described herein, the tracing control application is configured to instantiate the probes using an out-of-band management interface of the EDA emulator.

According to another aspect of the subject matter described herein, the system for EDA deep tracing and event correlation includes an artificial intelligence (AI) probe recommender for generating a recommended probe configuration in response to input from a user or captured by the test system and wherein the tracing control application is configured to dynamically instantiate the probes in accordance with the recommended probe configuration generated by probe the AI probe recommender.

According to another aspect of the subject matter described herein, the emulated data center traffic includes data emulating an artificial intelligence/machine learning (AI/ML) workload.

According to another aspect of the subject matter described herein, the system for EDA deep tracing and event correlation includes a path emulation element configured to emulate a data center traffic path by adding an emulated impairment to the emulated data center traffic and/or emulating processing or storage of the emulated data center traffic by a datacenter switching fabric.

According to another aspect of the subject matter described herein, a non-transitory computer readable medium having stored thereon executable instructions that when executed by a processor of a computer controls the computer to perform steps is provided. The steps include dynamically instantiating a plurality of probes in a test system and an electronics design automation (EDA) emulator to capture data relating to events concerning processing or transmission of emulated data center traffic and/or traffic transmitted by the EDA emulator. The steps further include generating, by the test system, the emulated data center traffic. The steps further include transmitting, by the test system, the emulated data center traffic to the EDA emulator. The steps further include capturing, by the probes, data relating to the events concerning processing or transmission of the emulated data center traffic and/or the traffic transmitted by the EDA emulator. The steps further include correlating the data relating to the events concerning the processing or transmission of the emulated data center traffic and/or the traffic transmitted by the EDA emulator. The steps further include outputting, to a test system user, results of the correlating of the data relating to the events concerning the processing or transmission of the emulated data center traffic and/or the traffic transmitted by the EDA emulator.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps.

Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a diagram of a hardware and software stack for EDA testing using AI/ML workload emulation;

FIG. 2 is a diagram illustrating an example of dropped packet event tracing;

FIG. 3 is a diagram illustrating EDA testing including probing the EDA testing software stack using dynamically instantiated software probes at multiple levels in the software stack and in the EDA emulator;

FIG. 4 is a block diagram illustrating an exemplary deep tracing architecture for a test system in which probes are implemented using enhanced Berkley packet filters;

FIG. 5 is a block diagram illustrating in-band and out-of-band probe control;

FIG. 6 is a block diagram illustrating the use of an AI probe recommender to provide probe configuration input to a tracing control application; and

FIG. 7 is a flow chart illustrating an exemplary process for EDA deep tracing and event correlation.

### DETAILED DESCRIPTION

The subject matter described herein is intended for use with a DUT implemented by an EDA emulator, which is configured to test a pre-silicon chip design. A pre-silicon chip design is an HDL-implemented version of a chip design that needs to be tested for functionality and performance before committing the design to hardware. An EDA emulator executes the chip emulation using a clock local to the emulator. The clock local to the emulator provides a timing domain that is referred to herein as the EDA emulator time domain.

As stated above, one key need of EDA emulation platforms is the ability to test a pre-silicon chip design with realistic network traffic associated with high-performance distributed processing tasks, such as artificial intelligence/machine learning (AI/ML) workload tasks. Such testing requires coordination between test traffic generators, AI/ML workload simulators, and the EDA emulator.

The subject matter described herein achieves robust testing of an electronics design under test by using network test system components to handle the complexities involved in generating high-fidelity packet traffic that is representative of AI/ML workload processing in a realistic/complex distributed computing environment (i.e., environments that include complex switching fabrics/topologies, complex congestion control mechanisms, realistic impairment mechanisms, etc.) and further allows EDA platform users to easily manipulate AI/ML workload configurations (e.g., collective communication strategies, distributed processor models/types, switching fabric types and attributes, etc.).

Challenges associated with testing an EDA design under test include probing events at different protocol layers and correlating data from the probes. The subject matter described herein implements deep tracing and analysis of complex stacks, such as a test system running emulated collective communications workloads, to allow end-users to understand behavior at different levels. One example of a network protocol stack that may be emulated includes a test server, traffic generation agents, and a remote direct memory access (RDMA) over converged Ethernet (RoCE) version 2 (hereinafter, “RoCE”) transport layer. Other transport layers could be used, including Falcon, ultra Ethernet transport (UET), etc. Different application layers can also be used, including libfabric, NCCL (Nvidia Collective Communications Library), other “*CCL's,” MPI (message passing interface), etc.

In one example use case, an RDMA memory write operation results in one or more packets being sent in sequence. In lieu of a proper and timely acknowledgement from the recipient, a sender will assume the packet was dropped and retransmit packet(s). The subject matter described herein is capable of tracing such behavior, whether forced (through deliberate impairments), or unexpected, through the following hardware and software layers, to reconstruct the entire event and determine where the packet was dropped and if all system components behaved correctly.
Test application layer
Library—ibverbs or libfabric userspace driver
Transport—SoftRoCE network kernel driver
Data Link—Ethernet or virtual Ethernet/virtio driver
EDA emulation adapter hardware/software
Emulated DUT

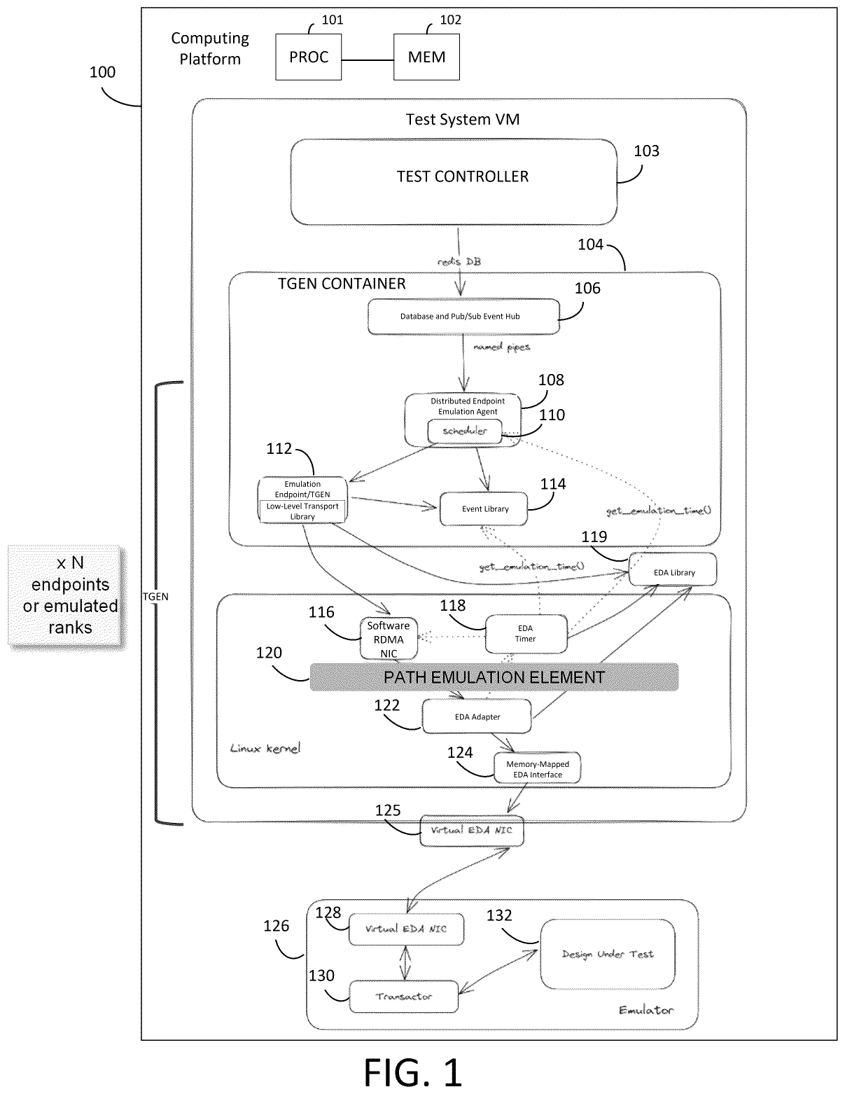

FIG. 1 is a diagram of a hardware and software stack for EDA testing using AI/ML workload emulation. Referring to FIG. 1, test system 100 includes a computing platform having at least one processor 101 and a memory 102. Test system 100 further includes a test system virtual machine 103 in which the components that test an EDA design under test execute. Test system VM 103 includes a test controller 102 that controls the overall operation of the test system. Test system VM 103 also includes a traffic generation container 104 that contains user-space traffic generation components of the test system. The traffic generation components include a database and publish/subscribe (pub/sub) event hub 106 that receives commands from test controller 102 and forwards the commands to traffic generation components. A distributed endpoint emulation element 108 includes a scheduler 110 that schedules traffic generation by emulation endpoints/traffic generators, such as emulation endpoint/traffic generator 112. An event library 114 includes functions used by traffic generation components to generate and send emulated traffic to an EDA design under test.

The test system illustrated in FIG. 1 also includes kernel space test components. The kernel space test components include software emulation of a remote direct memory access (RDMA) network interface card (NIC) 116, an EDA timer 118, a path emulation element 120, an EDA adapter 122, and memory mapped EDA interface 124. Software RDMA NIC 116 receives emulated traffic from emulation endpoint/traffic generator 112 and generates the corresponding RDMA commands. EDA timer 118 implements timing in EDA emulator time. An EDA library 119 includes functions usable by test system components for communicating with EDA emulator 126. Path emulation element 120 emulates data center switching paths, including path impairments, packet processing, packet storage, etc. EDA adapter 122 communicates with memory mapped EDA interface 124. Virtual EDA NIC 125 communicates directly with EDA emulator 126.

EDA emulator 126 includes virtual EDA NIC 128, a transactor 130, and EDA design under test 132. Virtual EDA NIC 128 communicates with test system 100 at the packet level. Transactor 130 provides the interface to design under test 132. Design under test 132 emulates an electronic design, such as a switching component design, that is being evaluated before committing the design to hardware.

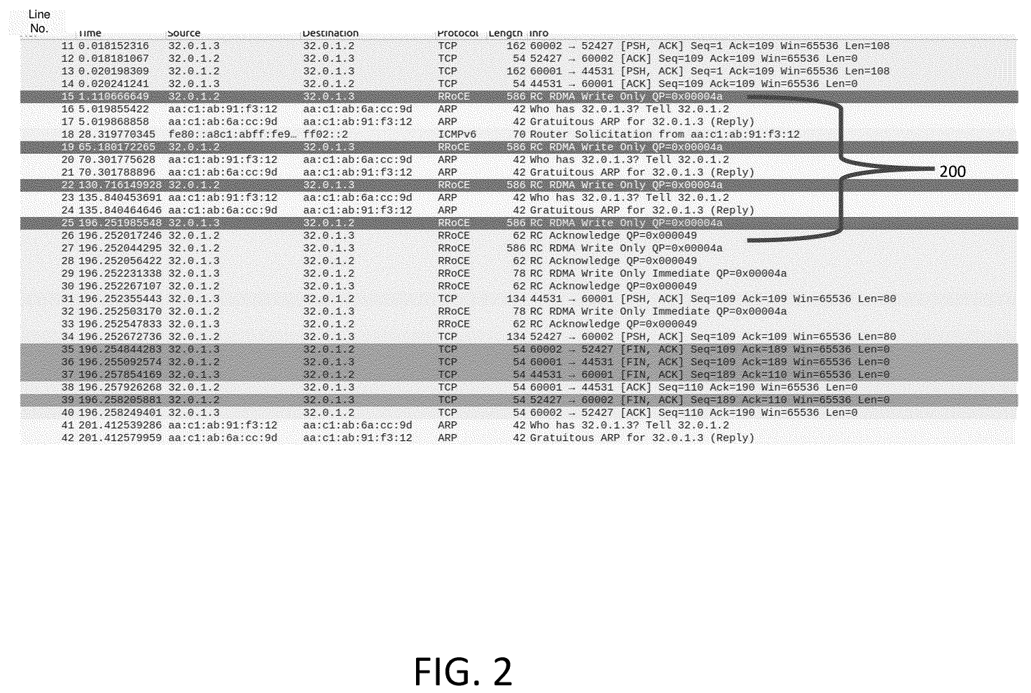

It is desirable to probe the test system and the EDA emulator illustrated in FIG. 1 and to correlate events occurring at different levels in the test system and the emulator software and firmware stacks. Without the ability to probe the test system and emulator software and firmware stacks at multiple levels, one alternative method for monitoring and correlating the events occurring at the different levels is to manually analyze packet capture data, identify events in the packet capture data, and manually correlate the events. FIG. 2 is a diagram illustrating packet capture data from which events can be manually identified and correlated. Referring to FIG. 2, the packets within brackets 200 are related to a forced packet drop caused by a software impairment. The packet capture in FIG. 2 shows the packets being sent from one emulated GPU/RDMA NIC to another GPU/RDMA NIC. The captured packets do not include the input to the receiver, but capturing the input to the receiver would require even more correlation. The sender sends an “RC RDMA Write Only” packet in line 15. Path emulation element 120 artificially drops three packets of this type, and the sender keeps retransmitting (in this case after 65 seconds delay) until the receiver finally receives the fourth retransmission in line 25, and the receiver then sends an acknowledgement packet in line 26. The write transaction completes in line 33.

It is desirable to correlate this packet activity captured “on the wire” with the entire software stack's set of events, beginning with the high-level test controller application, through the layers on the previous page and draw inferences such as “at this moment in time, the test system called the ibverbs function to initiate an RDMA write transfer, and the initial packet had to be retransmitted three times” without manually combing through packet captures and performing laborious, ad hoc software event traces.

Instead, it is desirable for the event information to be selectively gathered continuously for post-mortem analysis or even regression-testing, auditing, etc., for later inspection, drilldown, etc. It is desirable to have the test system analyze and draw inferences by correlating events. For example, markers in a packet, such as “queue pairs” (QPs), sequence numbers, IP addresses, etc., can be correlated to string together a chain of events or detect missing events.

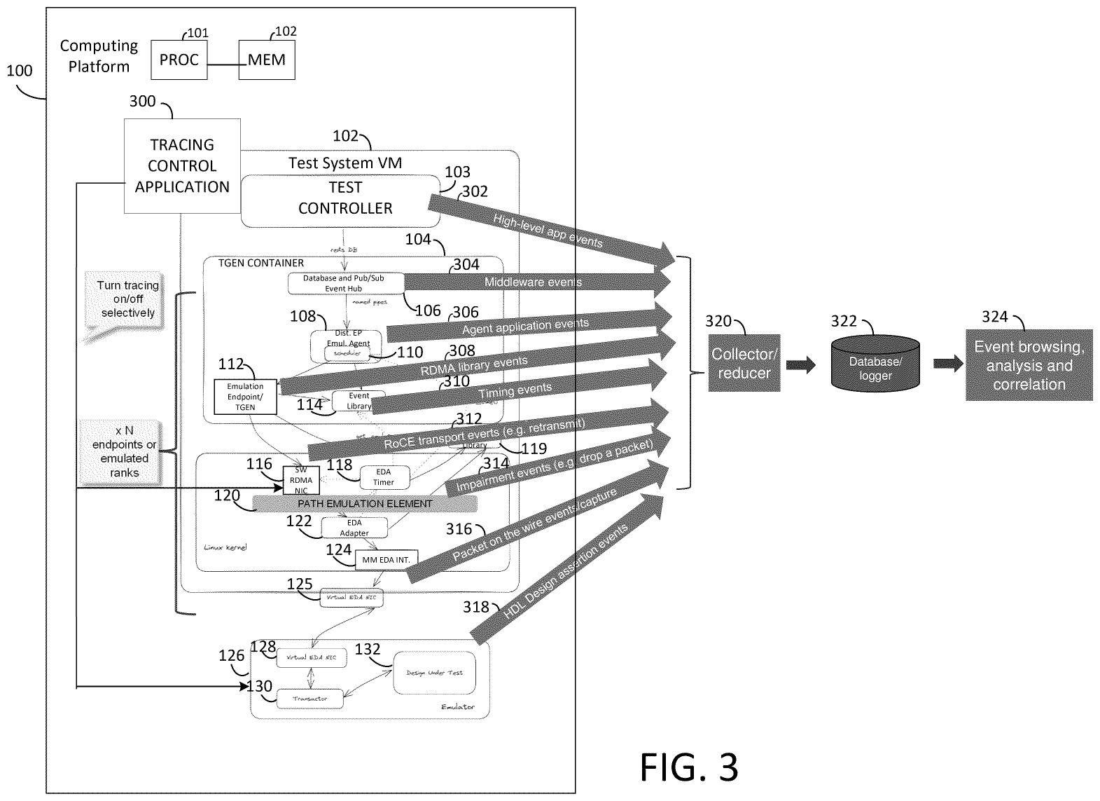

Rather than requiring a user to manually analyze packet capture files to detect and correlate events, the test system described herein dynamically instantiates probes to detect events at multiple levels in the test system and EDA emulator software and firmware stacks, automatically correlates the events captured/detected by the probes, and generates output that identifies the correlated events that occurred at the different levels. FIG. 3 illustrates a tracing control application that selectively activates probes at different levels of the test system and EDA emulator software and firmware stacks. Referring to FIG. 3, test system 100 and EDA emulator 126 include the same components illustrated in FIG. 1. In addition, test system 100 includes a tracing control application 300 that selectively activates and deactivates probes at the different levels. Tracing control application 300 may allow a user to identify probes, probe groups, probe types, probe scopes (i.e., hierarchical levels), specify filters, etc., as well as probe state, i.e. enabled/disabled, etc. In the illustrated example, tracing control application 300 may dynamically instantiate a test controller application layer probe 302 to capture high level application events related to EDA testing. It is understood that dynamically instantiating a probe includes activating the probe to begin capturing events. Tracing control application 300 may also dynamically deactivate probes, for example, in response to user input and/or detection of the event for which a given probe is configured to detect. Tracing control application 300 may dynamically instantiate a middleware layer probe 304 to capture events produced by database and pub/sub event hub 106. Tracing control application 300 may dynamically instantiate an agent application events probe 306 to capture events produced by distributed endpoint emulation agent 108. Tracing control application 300 may dynamically instantiate an RDMA events probe 308 to capture RDMA library events. Tracing control application 300 may dynamically instantiate a timing events probe 310 to capture timing related events in the test system. Tracing control application 300 may dynamically instantiate an RoCE events probe 312 to capture RoCE transport events, such as packet retransmissions at the RoCE layer. Tracing control application 300 may dynamically instantiate a path emulation element probe 314 to capture events related to emulated data center switching paths, including path impairments, packet processing, and packet storage. Tracing control application 300 may dynamically instantiate an RDMA NIC probe to capture packets on the wire and related events. Tracing control application 300 may dynamically instantiate an EDA emulator probe in EDA emulator 126 to capture events associated with the emulated design under test.

Each of probes 302-318 may be implemented in software that reads data written to memory by the test or EDA emulator component being monitored and sends the data to a collector/reducer 320. In one example that will be described in more detail below, probes 302-318 may be implemented using enhanced Berkeley packet filters (eBPFs).

Collector/reducer 320 receives the data relating to the events captured by probes 302-318 and stores the event data in a database/logger 322. An event browser/analyzer/correlator 324 correlates data relating to the events, allows the user to browse the uncorrelated and correlated event data.

The architecture illustrated in FIG. 3 can be used to reconcile between test system and emulator timing domains. Some events occurring in test system 100 may use the normal real-world time-of-day. For full-stack event analysis, the events occurring in test system 100 need to be correlated with events recorded from EDA emulator 126 in the EDA time-domain. Some processes/function blocks may straddle two time domains and utilize both time domains.

Some events occurring in the architecture illustrated in FIG. 3 may be associated with the time-domain of EDA emulator 126, which has a synthetic “time of day” or “EDA wall-clock.” The software stack of test system 100 synchronizes to and uses the EDA clock to govern its operation. For example, the EDA clock helps define packet generation “rates.” The EDA clock is also used as a timestamp to record significant events and is used for logging, tracing and probing.

One aspect of the subject matter described herein includes selectively recording EDA emulator timestamps and test system timestamps (where available) for certain events, so that events can be correlated properly. The dual timestamps may be stored as part of the record for an event detected by probes 302-318.

Another approach, which can be used simultaneously with the approach described in the preceding two paragraphs, is to record the real-world time and the EDA time as a tuple whenever the EDA issues a time update to us. This would provide a “Rosetta Stone” which allow test system 100 to freely translate between the two time domains and reconcile events. Graphs and logs generated by test system 100 may include both timelines.

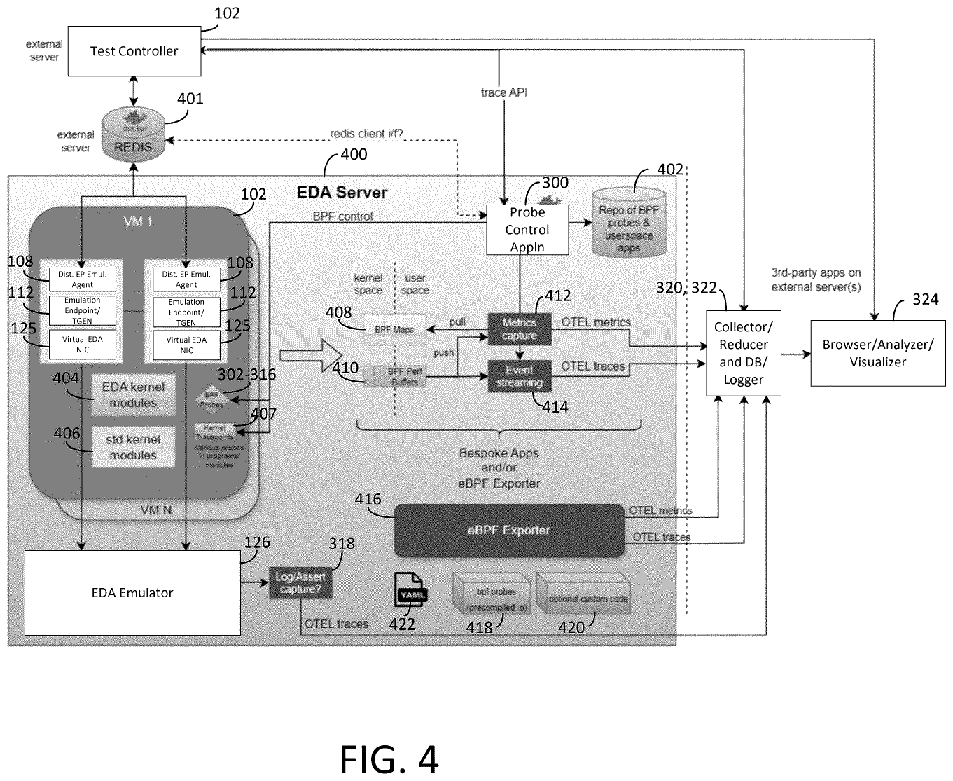

FIG. 4 is a block diagram illustrating an exemplary deep tracing architecture for test system 100 in which probes are implemented using eBPFs. Referring to FIG. 4, test controller 102 may reside on an external server and control the overall operation of probing and testing of the emulated design under test. Test controller 102 may interface with test system VM 102 executing on an EDA server 400 via a Redis interface 401. Tracing control application 300 accesses a repository 402 of BPF probes and user space applications and uses the data in repository 402 to dynamically instantiate probes, such as probes 302-318. Probes 302-316 probe any user space or kernel space modules in test system 100, including EDA kernel modules 404, standard kernel modules 406, or any of the modules illustrated in FIG. 3. Kernel tracepoints 407 are embedded in kernel code to detect kernel events.

Data collected by probes 302-316 is stored in BPF maps 408, which span kernel space and user space. BPF perf or ring buffers 410 are used to transfer streaming output (events) of probes 302-316. A metrics capture application 412 captures open telemetry (OTEL) metrics and provides the metrics to collector/reducer 320, which stores the metrics in database/logger 322. Event monitor 414 provides open telemetry traces to collector/reducer 320, which stores the traces in database/logger 322. The open-source eBPF Exporter tool 416 can augment the architecture with a simple and standardized framework, making it convenient to list the probes to be monitored. The probes can include precompiled probes 418 and/or custom probes 420. The probes can be written in any suitable language or format. In one example, the probes are written in a markup language format, as indicated by yet another markup language (YAML) 422.

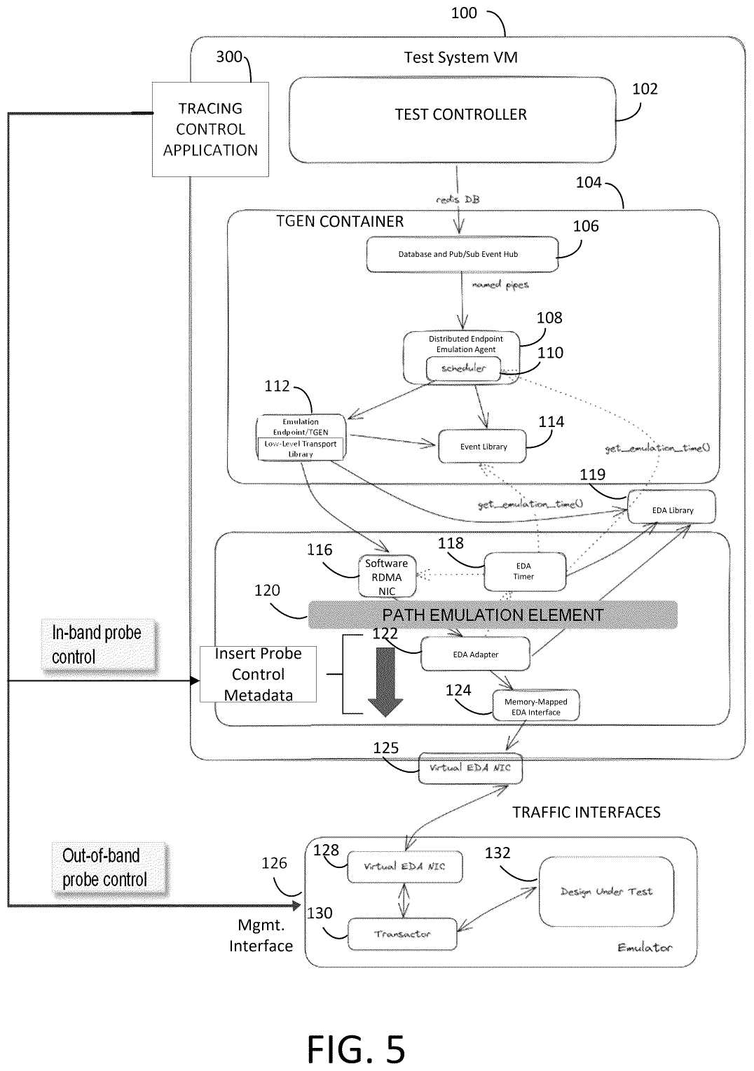

The probe architecture can be controlled using in-band and/or out-of-band control. FIG. 5 is a block diagram illustrating in-band and out-of-band probe control. During testing of EDA design under test 132, tracing control application 300 communicates traffic and metadata to EDA emulator 126 through transactors, such as transactor 130, which are virtio network interfaces (shared memory ring buffers between the app running as test system VM 103 and other software entities in EDA server 403). In performing in-band probe control, tracing control application 300 inserts probe control metadata in or between packets transmitted to EDA emulator 126. Tracing control application 300 may add the probe control metadata to an emulated traffic packet, in an inter-frame gap between frames sent to EDA emulator 126, and/or in an EDA wall clock sent to EDA emulator 126. In-band probe control metadata insertion may be performed in the interface between a traffic source (e.g., a SoftRoCE source) and the EDA interface layers (adapter, transactor, etc.). Metadata can also be sent in-band as dedicated control packets with no test traffic contents.

Metadata can be used to control tracing and probing in EDA emulator 126 by creating new metadata messages which support the features/options described above. Probing control can be performed with per-packet granularity if needed. Probing control with per-packet granularity may allow very detailed tracing for a limited scope and time span, allowing for deep analysis without generating excessive data.

Out-band probe control may be performed using a management interface of EDA emulator 126 accessed by tracing control application 300. In one example, the management interface may be an Ethernet interface of EDA emulator 126 used for managing EDA functions, but that is also used herein for out-of-band probe control. The out-band probe control interface may not have packet-level granularity like the in-band approach. However, the same semantics for probe identification and commands could be supported.

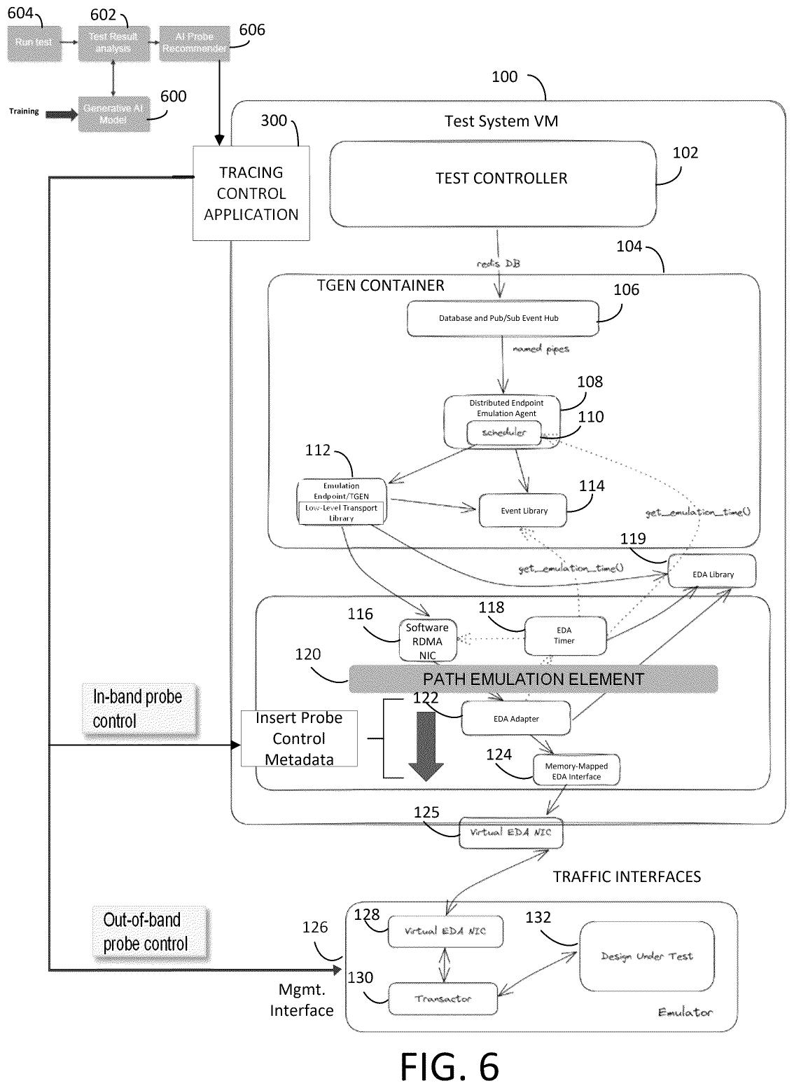

According to another aspect of the subject matter described herein, probing configuration for an EDA emulation system can be generated by an artificial intelligence (AI) probe recommender. FIG. 6 is a block diagram illustrating the training of a generative AI model to produce the trained model, which is referred to herein as the AI probe recommender, and the use of the AI probe recommender to provide probe type, placement, and configuration input to tracing control application 300. Referring to FIG. 6, a generative AI model 600 is trained using manually input test and probe configuration data and corresponding EDA test results and analysis 602 generated from running EDA test 604. An example of training an AI model to generate test configuration data is found in commonly-assigned co-pending U.S. Patent Application Publication No. 2024/0378125, the disclosure of which is incorporated herein by reference in its entirety. Once trained, generative AI model 600 can function as AI probe recommender 606, which receives, as input, text prompts from the test system user and generates, as output to tracing control application 300, probe configuration data. For example, test system user may input a text prompt, such as, “help me set up probes to trace tail latency in processing of RDMA traffic”. In response, AI probe recommender 606 may generate a probe configuration that includes at least one probe in test system 100 and at least one probe in EDA emulator 126 to capture events relating to diagnosing network traffic tail latency.

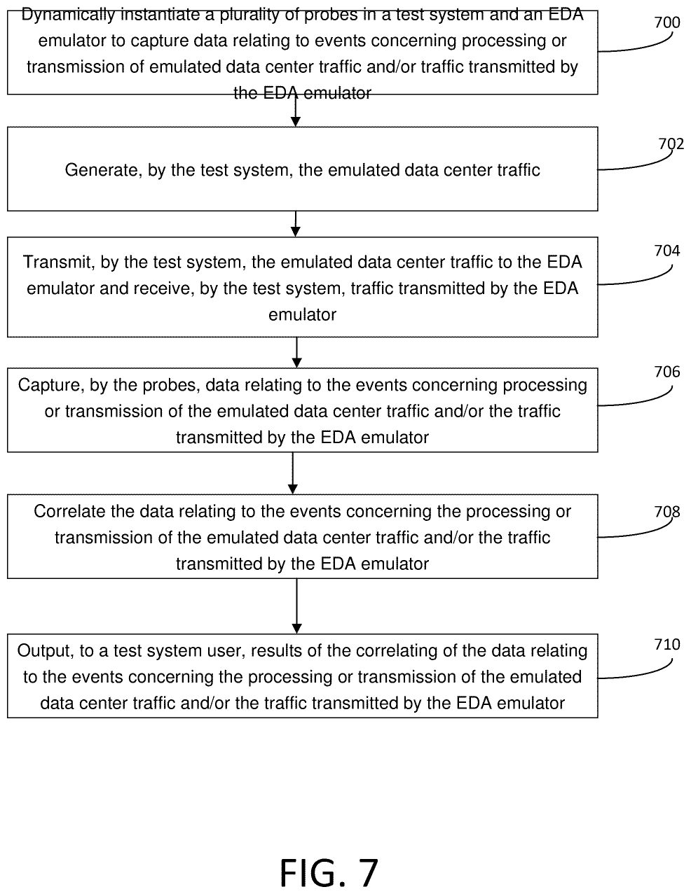

FIG. 7 is a flow chart illustrating an exemplary process for EDA deep tracing and event correlation. Referring to FIG. 7, in step 700, the process includes dynamically instantiating a plurality of probes in a test system and an EDA emulator to capture data relating to events concerning processing or transmission of emulated data center traffic and/or traffic transmitted by the EDA emulator. Tracing control application 300 may create one or more probes in response to a tracing request from a user. In one example, a hardware design under test, such as emulated design under test 132, may emit data relating to events in a compact binary streaming format into a PCIe-bus-accessible FIFO or memory table. A software adapter could read this event data and convert the event data into a perfbuffer or a ring buffer version, accessible through functions provided by a Berkeley packet filter library, referred to as libbpf. The adapter would include tooling which generates the data and metadata (symbol tables, etc.) Libbpf thinks it's probing the adapter (which presents maps and perf/ring buffers) but in reality, libbpf is receiving the data from emulated design under test 132.

Libbpf could also be extended to accommodate this hybrid architecture more naturally by allowing for userspace programs to bind to memory and I/O interfaces of emulated design under test 132 instead of memory structures managed by the Linux OS. Likewise, the notion of injecting eBPF bytecode or just in time (JIT)-compiled code for probe instantiation and probe activation by inserting jumpoints in running code, could be supplanted by the capability to instantiate and activate probes directly in EDA emulator 126 through an agreed-upon interface, such as memory or register-mapped commands over the PCIe bus, etc.

The probes may be instantiated before or during the transmission and sending of test packets to the EDA design under test. For example, probes may be established before a test using the out-of-band control mechanism described above. Probes may be instantiated during a test using in-band-probe control metadata transmitted with or between test packets or using the out-of-band control mechanism described above.

In step 702, the process includes generating, by the test system, the emulated data center traffic. For example, test system 100 may generate emulated data center packets to be transmitted to EDA emulator 126. The emulated data center traffic may be RDMA over converged Ethernet (RoCE) packets carrying data relating to an emulated AI or ML workload.

In step 704, the process includes transmitting, by the test system, the emulated data center traffic to the EDA emulator and receiving, by the test system, traffic transmitted by the EDA emulator. For example, test system 100 may transmit the emulated data center packets to EDA emulator 126 via virtual EDA NICs 125 and 128 and receive responsive traffic, such as acknowledgements, transmitted by EDA emulator 126.

In step 706, the process includes capturing, by the probes, data relating to the events concerning processing or transmission of the emulated data center traffic and/or the traffic transmitted by the EDA emulator. For example, the probes may each read the data relating to their respective events from the configured memory locations in the test system or the EDA emulator where traffic is temporarily stored as the traffic traverses the different layers of the test system or the EDA emulator.

In step 708, the process includes correlating the data relating to the events concerning the processing or transmission of the emulated data center traffic. For example, event browser/analyzer/correlator 324 may read the data collected from different probes in database/logger 322 and identify data from different probes as relating to the same event. For example, event browser/analyzer/correlator 324 may read an RDMA over converged Ethernet packet and timestamp captured by RoCE events probe 312 prior to impairment. Event browser/analyzer/correlator 324 may use packet header information from the captured RoCE packet to locate a corresponding impaired packet captured by path emulation element probe 314 to capture events related to emulated data center switching paths, including path impairments, packet processing, and packet storage. Event browser/analyzer/correlator 324 may use the same packet header information to located PCIe data captured by an EDA emulator probe in EDA emulator 126 relating to the transmitted RoCE packet or the response from EDA emulator 126.

In step 710, the process includes outputting, to a test system user, results of the correlating of the data relating to the events concerning the processing or transmission of the emulated data center traffic and/or the traffic transmitted by the EDA emulator. For example, event browser/analyzer/correlator 324 may output the correlated packet data captured by the different probes along with the corresponding capture timestamps so that the test system user can diagnose causes of performance and/or functionality issues encountered during testing.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for electronics design automation (EDA) deep tracing and event correlation, the method comprising:
dynamically instantiating a plurality of probes in a test system and an EDA emulator to capture data relating to events concerning processing or transmission of emulated data center traffic and/or traffic transmitted by the EDA emulator;
generating, by the test system, the emulated data center traffic;
transmitting, by the test system, the emulated data center traffic to the EDA emulator and receiving, by the test system traffic transmitted by the EDA emulator;
capturing, by the probes, data relating to the events concerning processing or transmission of the emulated data center traffic and/or the traffic transmitted by the EDA emulator;
correlating the data relating to the events concerning the processing or transmission of the emulated data center traffic and/or the traffic transmitted by the EDA emulator; and
outputting, to a test system user, results of the correlating of the data relating to the events concerning the processing or transmission of the emulated data center traffic and/or the traffic transmitted by the EDA emulator.

2. The method of claim 1 wherein dynamically instantiating the probes includes dynamically instantiating at least one probe in the test system and at least one probe in the EDA emulator.

3. The method of claim 2 wherein dynamically instantiating at least one probe in the test system includes instantiating a first probe for capturing data relating to emulated packets generated by the test system or packets received by the test system and a second probe for capturing data relating to emulated packets received by the EDA emulator or packets transmitted by the EDA emulator.

4. The method of claim 1 wherein dynamically instantiating the probes includes dynamically instantiating the probes using in-band probe control metadata.

5. The method of claim 4 wherein dynamically instantiating the probes including the in-band probe control metadata includes adding the in-band probe control metadata to or between packets in the emulated data center traffic transmitted by the test system to the EDA emulator.

6. The method of claim 1 wherein dynamically instantiating the probes includes dynamically instantiating the probes using an out-of-band management interface of the EDA emulator.

7. The method of claim 1 wherein dynamically instantiating the probes includes dynamically instantiating the probes in accordance with a recommendation provided by an artificial intelligence (AI) probe recommender.

8. The method of claim 1 wherein generating the emulated data center traffic includes generating, at an application layer of the test system, data emulating an artificial intelligence/machine learning (AI/ML) workload and forwarding the data emulating the AI/ML workload to a traffic generator/emulator, which generates the emulated data center traffic.

9. The method of claim 8 comprising transmitting the emulated data center traffic to a path emulation element, and at the path emulation element, emulating a data center traffic path.

10. The method of claim 9 wherein emulating the data center traffic path includes adding an impairment to the emulated data center traffic and/or emulating processing or storage of the emulated data center traffic by a data center switching fabric.

11. A system for electronics design automation (EDA) deep tracing and event correlation, the system comprising:
a computing platform including at least one processor and a memory;
a tracing control application implemented by the at least one processor for dynamically instantiating a plurality of probes in a test system and an EDA emulator to capture data relating to events concerning processing or transmission of emulated data center traffic and/or traffic transmitted by the EDA emulator;
an emulation endpoint/traffic generator for generating the emulated data center traffic and transmitting the emulated data center traffic to the EDA emulator and receiving traffic from the EDA emulator;
wherein the probes are configured to capture data relating to the events concerning processing or transmission of the emulated data center traffic and/or traffic transmitted by the EDA emulator;
an event browser/analyzer/reducer for correlating the data relating to the events concerning the processing or transmission of the emulated data center traffic and/or the traffic transmitted by the EDA emulator and outputting, to a test system user, results of the correlating of the data relating to the events concerning the processing or transmission of the emulated data center traffic and/or the traffic transmitted by the EDA emulator.

12. The system of claim 11 wherein the tracing control application is configured to dynamically instantiate at least one probe in the test system and at least one probe in the EDA emulator.

13. The system of claim 12 wherein the tracing control application is configured to dynamically instantiate a first probe for capturing data relating to emulated packets generated by the test system or packets received by the test system and a second probe for capturing data relating to emulated packets received by the EDA emulator or packets transmitted by the EDA emulator.

14. The system of claim 11 wherein the tracing control application is configured to dynamically instantiate the probes using in-band probe control metadata.

15. The system of claim 14 wherein the tracing control application is configured to add the in-band probe control metadata to or between packets in the emulated data center traffic transmitted by the test system to the EDA emulator.

16. The system of claim 11 wherein the tracing control application is configured to instantiate the probes using an out-of-band management interface of the EDA emulator.

17. The system of claim 11 comprising an artificial intelligence (AI) probe recommender for generating a recommended probe configuration in response to input from a user and wherein the tracing control application is configured to dynamically instantiate the probes in accordance with the recommended probe configuration generated by probe the AI probe recommender.

18. The system of claim 11 wherein the emulated data center traffic includes data emulating an artificial intelligence/machine learning (AI/ML) workload.

19. The system of claim 11 comprising a path emulation element configured to emulate a data center traffic path by adding an impairment to the emulated data center traffic and/or emulating processing or storage of the emulated data center traffic by a data center switching fabric.

20. A non-transitory computer readable medium having stored thereon executable instructions that when executed by a processor of a computer controls the computer to perform steps comprising:
dynamically instantiating a plurality of probes in a test system and an electronics design automation (EDA) emulator to capture data relating to events concerning processing or transmission of emulated data center traffic and/or traffic transmitted by the EDA emulator;
generating, by the test system, the emulated data center traffic;
transmitting, by the test system, the emulated data center traffic to the EDA emulator and receiving, by the test system, the traffic transmitted by the EDA emulator;
capturing, by the probes, data relating to the events concerning processing or transmission of the emulated data center traffic and/or the traffic received from the EDA emulator;
correlating the data relating to the events concerning the processing or transmission of the emulated data center traffic and/or the traffic transmitted by the EDA emulator; and
outputting, to a test system user, results of the correlating of the data relating to the events concerning the processing or transmission of the emulated data center traffic and/or the traffic transmitted by the EDA emulator.
